(19) United States
(12) Patent Application Publication
(10) Pub. No.: US 2005/0147754 A1
(43) Pub. Date: Jul. 7, 2005

(54) Zirconium complex useful in a CVD method and a thin film preparation method using the complex

(75) Inventors: Koji Yoda, Saitama (JP); Yuzo Tasaki, Tokyo (JP)

Correspondence Address: AKIN GUMP STRAUSS HAUER & FELD L.L.P., ONE COMMERCE SQUARE, 2005 MARKET STREET, SUITE 2200, PHILADELPHIA, PA, 19103-7013, US

(73) Assignees: Saes Getters S.p.A.; Toshima Manufacturing Co. Ltd.

(21) Appl. No.: 11/040,375

(22) Filed: Jan. 21, 2005

Related U.S. Application Data
(63) Continuation of application No. PCT/IT03/00445, filed on Jul. 18, 2003.

(30) Foreign Application Priority Data
Jul. 22, 2002 (JP) 2002-244354

(51) Int. Cl. C23C 16/06; C07F 7/28

(52) U.S. Cl. 427/255.36; 556/54

(57) ABSTRACT

In the preparation of a PZT (Pb/Zr/Ti) thin film by a liquid source CVD method, the use of zirconium tetrakis(isobutyrylpivaloylmethanate) as a zirconium precursor allows a constant composition ratio of films to be obtained within a wide range of substrate temperature and negates the need for thermal treatment after the film preparation. Accordingly, this preparation method provides a PZT thin film having a constant quality at a low cost.

### CROSS-REFERENCE TO RELATED APPLICATIONS

This application is a continuation of International Application No. PCT/IT2003/000445, filed Jul. 18, 2003, which was published in the English language on Jan. 29, 2004, under International Publication No. WO 2004/009867, and the disclosure of which is incorporated herein by reference.

### BACKGROUND OF THE INVENTION

The present invention relates to a precursor and a precursor solution used for preparation of Zr-containing thin films by a chemical vapor deposition (CVD) method. In particular, the invention is directed to a precursor solution comprising a specific zirconium complex, which allows a constant composition ratio of Pb—Zr—Ti-type films (which comprises lead zirconate titanate and/or lead zirconate; hereinafter collectively referred to as “PZT”) to be consistently obtained within a wide range of substrate temperature in carrying out a liquid source CVD method.

In preparation of thin films by use of a CVD method, vapor sources of precursors are generally liquid materials at room temperature, such as trimethylgallium, a precursor used in the preparation of GaAs thin films; and tetraethoxysilane, a precursor used in the preparation of SiO₂ thin films. In a CVD method, reactant vapors are supplied by bubbling carrier gases through liquid precursors, evaporating the liquid precursors as reactant vapors and guiding the reactant vapors entrained in the carrier gas into a deposition chamber.

On the other hand, in the case of using a solid material as a precursor, it is impossible to employ the above bubbling method. A sublimation method is necessarily used for generation of reactant vapors from solid precursor materials, wherein the rate of supplying the reactant vapors is not stable in the CVD method.

In order to solve the above problems, the liquid source CVD method was developed, in which solid precursor materials are dissolved in organic solvents, such as tetrahydrofuran (THF), butyl acetate, toluene, and octane at a specific concentration. The thus-obtained solutions are injected into a vaporizer chamber at a high temperature at a constant injection rate controlled by a liquid flow meter. A constant amount of the reactant vapors can be obtained by vaporizing all of the injected solutions. At present, the liquid source CVD method is in popular use in the preparation of complex metal oxides thin films, as shown in Japanese published patent applications JP-H07-268634 and JP-H11-323558.

Among these complex metal oxides thin films, currently, PZT thin films are mostly researched and developed as capacitor layers for ferroelectric random access memories (FeRAMs). In the preparation of a PZT thin film by the CVD method, the liquid source CVD method is employed, since most of precursors are solid.

For example, Japanese Patent No. 3054118 shows metal complexes as a CVD precursor used in the preparation of PZT thin films, such as:
lead precursors including lead bis[dipivaloylmethanate] (Pb(DPM)₂), tetraethyl lead (PbEt₄), and triethylneopentyloxy lead (PbEt₃OCH₂C(CH₃)₃);
zirconium precursors including zirconium tetrakis[dipivaloylmethanate] (Zr(DPM)₄), tetra-tert-butoxy zirconium (Zr(O-t-Bu)₄), and zirconium tetrakis[diisobutyrylmethanate] (Zr(DIBM)₄); and
titanium precursors including diisopropoxy titanium bis[dipivaloylmethanate] (Ti(O-iso-Pr)₂(DPM)₂), di-tert-butoxytitanium bis[dipivaloylmethanate] (Ti(O-t-Bu)₂(DPM)₂), tetraisopropoxy titanium (Ti(O-iso-Pr)₄), and tetra-tert-butoxytitanium (Ti(O-t-Bu)₄).

In the liquid source CVD method, the composition ratio of the deposited film can be controlled to some extent by varying the mixing ratio of the precursor solutions. However, there are problems that the composition ratio of the film does not necessarily correspond to the supply ratio of the precursor solutions, and it changes due to fluctuations in the substrate temperature. As a reason for this, it can be mentioned that precursors have their own thermal decomposition activation energy, which are different from each other, and precursors tend to react mutually in the liquid or vapor phases, etc.

For the above reasons, it is preferable to select precursors having the same thermal decomposition activation energy and wherein the precursors do not react with each other. However, the combinations of the CVD precursors used for the preparation of PZT thin films, contemplated in the art, include PbEt₄/Zr(O-t-Bu)₄/Ti(O-t-Bu)₄; PbEt₃OCH₂C(CH₃)₃/Zr(O-t-Bu)₄/Ti(O-iso-Pr)₄; Pb(DPM)₂/Zr(DPM)₄/Ti(O-iso-Pr)₂(DPM)₂; Pb(DPM)₂/Zr(DIBM)₄/Ti(O-iso-Pr)₂(DPM)₂ and the like. These combinations have problems, such as volatility, toxicity, particle formation in a vapor phase, and the unstable composition ratio of the film due to fluctuations in the substrate temperature. The only combination used for the production of PZT thin films in industrial application is the above described Pb(DPM)₂/Zr(DIBM)₄/Ti(O-iso-Pr)₂(DPM)₂. In using the combination of Pb(DPM)₂/Zr(DIBM)₄/Ti(O-iso-Pr)₂(DPM)₂, the range of temperature in which a composition ratio of the film is not affected by a change of the substrate temperature is very narrow. Especially, there is a problem that the substrate temperature has to be controlled to a narrow range, because the amount of the deposited zirconium is remarkably affected by a change of the substrate temperature. Accordingly, an improved Zr-containing precursor used for the production of PZT thin films has been desired.

### BRIEF SUMMARY OF THE INVENTION

An object of the invention is therefore to provide a zirconium complex capable of overcoming the aforesaid problems. In the preparation of PZT thin films by the liquid source CVD method, using the zirconium complex of the invention not only widens the range of temperature in which the amount of the deposited zirconium is not affected by the change of the substrate temperature, but also the substrate temperature range overlaps the range of temperature in which the amounts of the deposited lead and the deposited titanium are not affected, and the composition ratio of the deposited film is stable.

The inventors have prepared and evaluated many complexes each having varied properties by changing structures of the complexes, including some zirconium complexes. Among them, it is found that using zirconium tetrakis[isobutyrylpivaloylmethanate] (hereinafter referred to as “Zr(IBPM)₄”) provides a wide range of the substrate temperature in which the amount of the deposited zirconium is stable, and that the temperature range overlaps the range of the substrate temperature in which the amounts of the deposited lead derived from Pb(DPM)₂ and the amounts of the deposited titanium derived from Ti(O-iso-Pr)₂(DPM)₂ are stable. Thus, the above object of the present invention has been achieved.

Zr(IBPM)₄ of the invention is not described in any of the prior art references known to applicants, such as Japanese patent No. 2799763, and the properties thereof are not known in the art. Hence, it is believed that Zr(IBPM)₄ is a novel complex.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown. In the drawings:

FIG. 1 is a graph obtained by thermogravimetry-differential thermal analysis (TG-DTA) of Zr(IBPM)₄ conducted in an argon atmosphere;

FIG. 2 is a graph obtained by TG-DTA of Zr(IBPM)₄ conducted in dry air;

FIG. 3(a) is a comparison graph of two DTA curves of Zr(IBPM)₄ obtained in dry air and in argon gas. FIG. 3(b) is a comparative plot showing relationships between the differential function (dDTA/dT) as a function of temperature (° C.), obtained in dry air and in argon gas;

FIG. 4 is a graph showing the relationships between metal deposition rates and substrate temperature in the preparation of PZT thin films, by using a combination of Zr(IBPM)₄/Pb(DPM)₂/Ti(O-iso-Pr)₂(DPM)₂ in Example 1;

FIG. 5 is a graph showing the relationships between metal deposition rates and substrate temperature in the preparation of PZT thin films by using a combination of Zr(DIBM)₄/Pb(DPM)₂/Ti(O-iso-Pr)₂(DPM)₂ in Comparative Example 1.

### DETAILED DESCRIPTION OF THE INVENTION

In the invention, Zr(IBPM)₄ is a complex represented by the following formula (I).

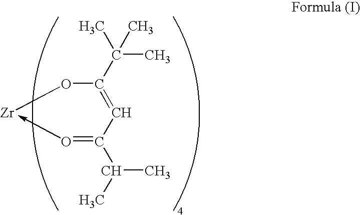

In the present invention, Zr(IBPM)₄ may be prepared by non-limiting example methods, such as those described below:
(1) Zirconium chloride (ZrCl₄) and isobutyrylpivaloylmethane ligand (2,2,6-trimethyl-3,5-heptanedione; C₁₀H₁₈O₂) are heated and refluxed in carbon tetrachloride while removing generated hydrogen chloride, and the solvent is evaporated under reduced pressure resulting in a crude product;
(2) ZrCl₄ is suspended in toluene and isobutyrylpivaloylmethane is added to the suspension. Then, after further addition of triethylamine and stirring, ZrCl₄ is completely dissolved in the solution and triethylamine chloride (Et₃N*HCl) precipitates in the reaction solution. Then, the reaction solution is filtered and the filtrate is evaporated under reduced pressure resulting in a crude product;
(3) To an ethanol-water (1:1 by weight) solution of zirconyl chloride hydrate (ZrOCl₂*nH₂O), sodium isobutyrylpivaloylmethanate (NaC₁₀H₁₇O₂) is added, and the precipitate is recovered by suction filtration and drying, resulting in a crude product.

The resulting crude product can be recrystallized from ethanol. The Zr content of the refined products is measured by inductively coupled plasma (ICP) spectrometry to obtain 11.9% by weight, which is equal to the theoretical value. The melting point of the refined products is measured by using a melting point apparatus equipped with an oil bath. The refined products do not melt at the highest limit of measurement of 270° C. (visually observed). The solubility in THF, butyl acetate, toluene, octane, and ethylcyclohexane is about 0.33 to 1 mole/liter.

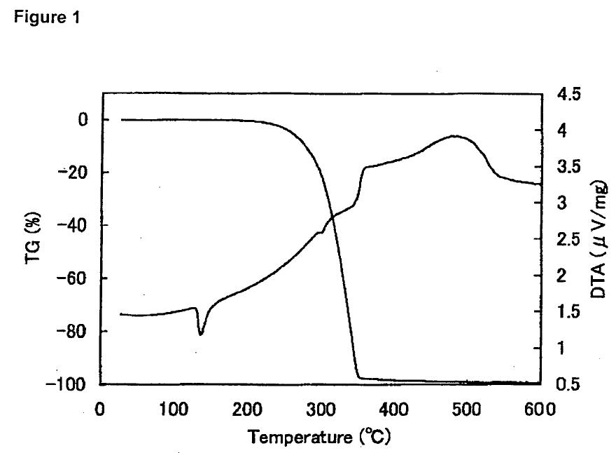

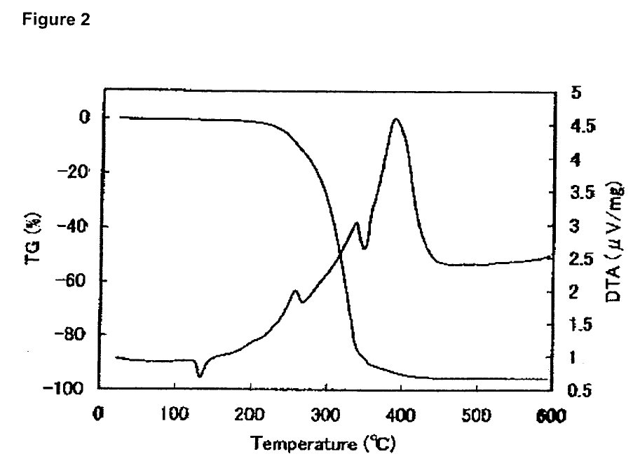

The thermal properties of Zr(IBPM)₄ are shown in FIG. 1 and FIG. 2 as results of the TG-DTA. In FIG. 1, the analysis was conducted in an argon atmosphere. From FIG. 1, it can be seen that Zr(IBPM)₄ has an excellent thermal stability.

With respect to the durability in oxidative degradation, precursors having a high oxidative degradation temperature have a problem that, at a substrate temperature of about 580° C., the oxidative degradation hardly occurs. Accordingly, Zr is hardly contained in the deposited metal film. Conversely, precursors having a low oxidative degradation temperature have a problem that, at a substrate temperature of about 580° C., the oxidative degradation easily occurs. Accordingly, particulate matter generated by the oxidative degradation deteriorates the surface evenness of the substrate and the deposited film.

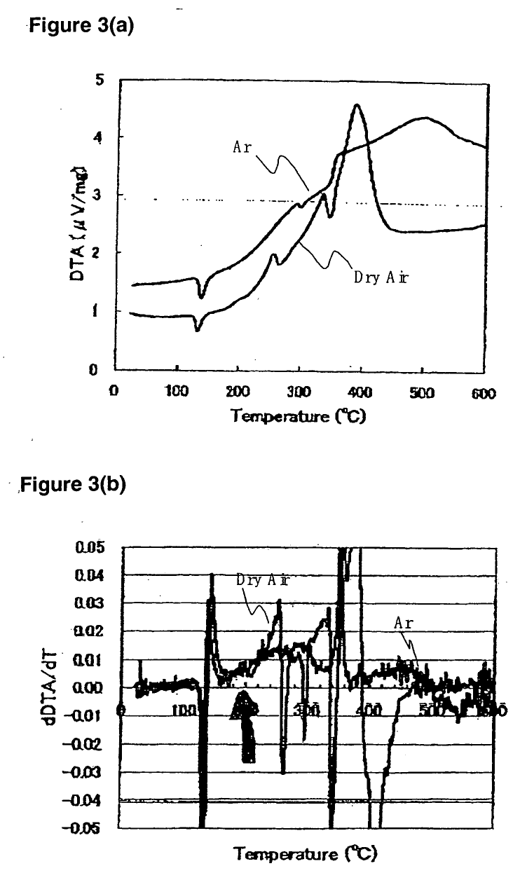

In FIG. 2, the measurement was conducted in dry air. FIG. 3(a) shows two DTA curves of Zr(IBPM)₄ obtained in dry air and in argon gas. FIG. 3(b) shows relationships between the differential function (dDTA/dT) and the temperature (° C.) obtained in dry air and in argon gas. From FIG. 3(b), it can be presumed that the temperature at which the caloric value difference between measurements in argon gas and in dry air began to increase was the temperature at which the exothermic oxidation reaction occurred. The temperatures at which oxidation reactions occurred were about 180° C. for Zr(IBPM)₄, about 130° C. for Zr(DIBM)₄ and about 280° C. for Zr(DPM)₄. From the results, it was found that Zr(IBPM)₄ has an excellent durability in oxidative degradation.

When Zr(IBPM)₄ is used as a CVD precursor for the preparation of a film, the liquid source CVD method is preferably employed, because the melting point of Zr(IBPM)₄ is higher than 200° C.

As for the solvent used for Zr(IBPM)₄ as a CVD precursor, preferred are organic solvents which do not react with Zr(IBPM)₄. Non limiting examples include THF, butyl acetate, toluene, octane, ethylcyclohexane, and the other solvents which are generally used in the liquid source CVD method. As for the concentration of the Zr(IBPM)₄ solution, preferred is about 0.05 to 0.5 mol/liter, more preferred is about 0.1 to 0.3 mol/liter.

In spite of the above description, the preferable solvents and the preferable range of concentrations vary dependent on the structures and types of the vaporizer chamber and the deposition chamber of the film preparation apparatus and the types of the CVD methods.

Pb(DPM)₂ is a complex represented by the following formula (II).

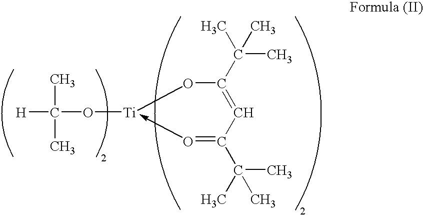

As for the precursor solvent used for Pb(DPM)₂, the above described solvent for Zr(IBPM)₄ can be mentioned. The solvent used for Pb(DPM)₂ can be the same as or different from one used for Zr(IBPM)₄. Also, the concentration of the Zr(IBPM)₄ solution may be about 0.05 to 0.5 mol/liter, preferably about 0.1 to 0.3 mol/liter. The concentration of the Pb(DPM)₂ solution can be the same as or different from that of the Zr(IBPM)₄ solution.

Ti(O-iso-Pr)₂(DPM)₂ is a complex represented by the following formula (III).

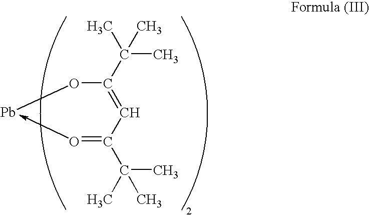

As for the precursor solvent used for Ti(O-iso-Pr)₂(DPM)₂, the above described solvent for Zr(IBPM)₄ can be mentioned. The solvent used for Ti(O-iso-Pr)₂ (DPM)₂ can be the same as or different from either one used for the Zr(IBPM)₄ solution or one used for the Pb(DPM)₂ solution. Also, the concentration of the Ti(O-iso-Pr)₂(DPM)₂ solution may be about 0.05 to 0.5 mol/liter, preferably about 0.1 to 0.3 mol/liter. The concentration of the Ti(O-iso-Pr)₂(DPM)₂ solution can be the same as or different from either one of the Zr(IBPM)₄ solution or one of the Pb(DPM)₂ solution.

In one embodiment of the method of the invention, each of the solution of Zr(IBPM)₄, the solution of Pb(DPM)₂ and the solution of Ti(O-iso-Pr)₂(DPM)₂ is supplied into the vaporizer chamber of the CVD apparatus simultaneously, in order to prepare a PZT thin film. From several preparations of the films, changing the substrate temperature, it is found that the deposition rate of Zr on the substrate is stable at a substrate temperature of about 460 to 600° C., whereas the deposition rates of Pb and Ti on the substrate are stable at a substrate temperature of about 500 to 600° C. and about 520 to 600° C., respectively. Accordingly, a PZT thin film having a constant composition ratio can be obtained consistently by using the Zr complex of the invention.

The range of the substrate temperature in which the PZT thin film having a constant composition ratio can be obtained consistently is generally about 500 to 630° C., preferably about 520 to 600° C., more preferably about 550 to 600° C.

In the method of the invention, the range of temperature in which the constant composition ratio of the film can be obtained consistently is broad. Consequently, in the invention, it is not necessary to control the substrate temperature tightly.

In general, the recrystallization annealing of PZT thin films prepared by the CVD method is conducted so as to impart electrical properties such as hysteresis (ferroelectricity). In the annealing treatment, films are heated at about 550° C. or more for 10 to 60 minutes. In the present invention, PZT thin films having excellent electrical properties can be obtained without using annealing treatment.

Further, in the range of the substrate temperature, there is an advantage in that a crystallized PZT thin film can be obtained without thermal treatment (annealing) after the film preparation.

Within the scope of the invention, similar effects can be obtained even if slight amounts of elements other than Pb, Zr and Ti are incorporated into PZT films.

In the invention, the three solutions of the above Zr(IBPM)₄, Pb(DPM)₂ and Ti(O-iso-Pr)₂(DPM)₂ may be pre-mixed before the vaporization. Also, the above Zr(IBPM)₄, Pb(DPM)₂ and Ti(O-iso-Pr)₂(DPM)₂ may be dissolved in one solution. However, it is may be necessary to conduct the CVD process immediately after mixing or dissolving, because the replacement of the different ligands of these complexes occurs with the passage of time.

### EXAMPLE 1

Each of Zr(IBPM)₄, Pb(DPM)₂ and Ti(O-iso-Pr)₂(DPM)₂ was dissolved in THF at a concentration of 0.3 mol/1 liter to obtain three solutions (a Zr precursor solution, a Pb precursor solution and a Ti precursor solution). These three solutions were supplied into the CVD apparatus simultaneously under the conditions of: a vaporizer temperature of 250° C., a pressure of 10 torr in the deposition chamber, an oxygen flow rate of 1000 cc/min, and an Ar carrier gas flow rate of 1200 cc/min; with feeding rates of a Zr precursor solution at 0.50 ml/min, of a Pb precursor solution at 0.53 ml/min, and of a Ti precursor solution at 0.51 ml/min. The film preparations were carried out on Pt substrates for 10 minutes, while changing the substrate temperature every 20° C. within the range of 440 to 640° C. The amounts of metals (Zr, Pb and Ti) deposited on the substrate were measured by use of ICP spectrometry.

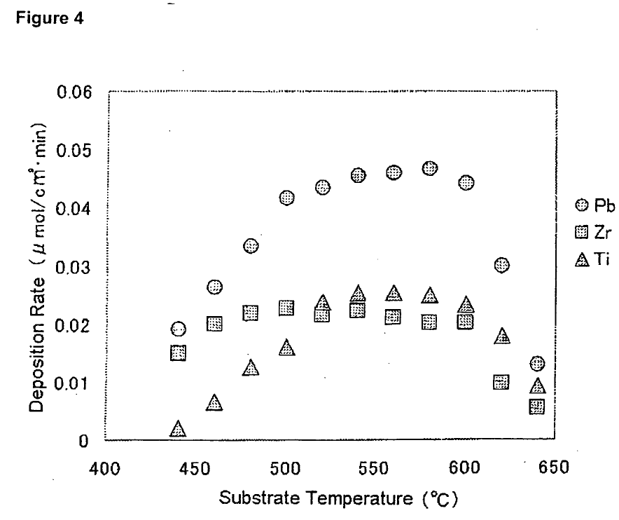

As can be clearly understood from the results of each metal deposition rate shown in FIG. 4, the range of the substrate temperature where stable Zr deposition rate can be obtained was about 460 to 600° C., and the ranges where stable Pb and Ti deposition rates can be obtained were about 500 to 600° C. and about 520 to 600° C., respectively. That is, the substrate temperature where a constant composition ratio of the PZT film can be obtained stably was in the range of about 520 to 600° C.

### COMPARATIVE EXAMPLE 1

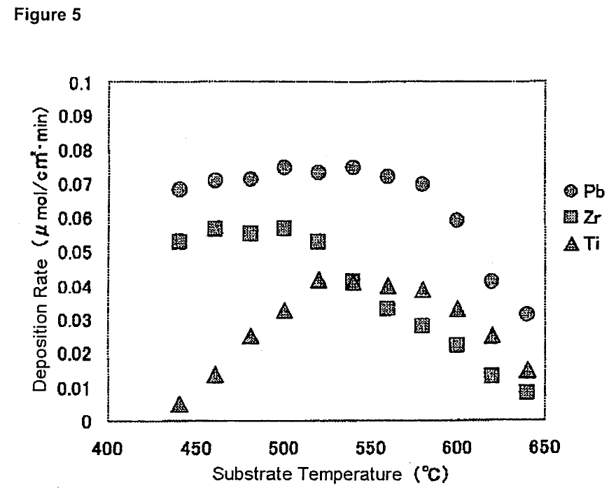

A PZT thin film was prepared in the same manner as in Example 1 with the exception that Zr(DIBM)₄ was substituted for Zr(IBPM)₄. The results of the metal deposition rates of the prepared film are shown in FIG. 5.

The range of the substrate temperature where the stable Zr deposition rate can be obtained was about 440 to 520° C., while the ranges where the stable Pb and Ti deposition rates can be obtained were about 440 to 580° C. and about 520 to 580° C., respectively. That is, the substrate temperature where a constant composition ratio of the PZT film can not be obtained in Comparative Example 1. In other words, in Comparative Example 1, to obtain a constant composition ratio of the film, it was necessary to control the substrate temperature tightly, for example precisely at 520° C.

### INDUSTRIAL APPLICABILITY

From the above, in the preparation of a PZT thin film by the liquid source CVD method, using Zr(IBPM)₄ of the invention as a zirconium precursor allows a constant composition ratio of films to be obtained within a wide range of the substrate temperature, and negates the need for thermal treatment after the film preparation. Therefore, the present invention provides a PZT thin film having a constant quality at a low cost.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1. Zirconium tetrakis(isobutyrylpivaloylmethanate) complex.

2. A method for preparing a Pb—Zr—Ti thin film, comprising using a composition comprising the zirconium complex according to claim 1 in a CVD method.

3. The method according to claim 2, wherein the composition is a precursor solution for preparation of a Pb—Zr—Ti thin film by a liquid source CVD method.

4. A method for preparation of a Zr-containing thin film by a liquid source CVD method, comprising using a precursor solution comprising zirconium tetrakis(isobutyrlpivaloylmethanate) complex.

5. The preparation method according to claim 4, wherein a precursor solution comprising diisopropoxy titanium bis(dipivaloylmethanate) complex is used with the precursor solution comprising zirconium tetrakis(isobutyrlpivaloylmethanate) complex.

6. The preparation method according to claim 4, wherein a precursor solution comprising lead bis(dipivaloylmethanate) complex is used with the precursor solution comprising zirconium tetrakis(isobutyrylpivaloylmethanate) complex.

7. The preparation method according to claim 5, wherein a precursor solution comprising lead bis(dipivaloylmethanate) complex is used with the precursor solution comprising zirconium tetrakis(isobutyrylpivaloylmethanate) complex

8. The preparation method according to claim 5, wherein a composition ratio of the thin film is stable at a substrate temperature of about 500° C. to 600° C.

9. The preparation method according to claim 6, wherein a composition ratio of the thin film is stable at a substrate temperature of about 500° C. to 600° C.

10. The preparation method according to claim 7, wherein a composition ratio of the thin film is stable at a substrate temperature of about 500° C. to 600° C.
